(19) United States
(12) Patent Application Publication
(10) Pub. No.: US 2002/0037631 A1
(43) Pub. Date: Mar. 28, 2002

(54) Method for manufacturing semiconductor devices

(75) Inventor: Tsutomu Mimata, Akiruno (JP)

Correspondence Address: KODA & ANDROLIA, 2029 Century Park East, Suite 3850, Los Angeles, CA, 90067-3024, US

(73) Assignee: KABUSHIKI KAISHA SHINKAWA

(21) Appl. No.: 09/961,222

(22) Filed: Sep. 21, 2001

(30) Foreign Application Priority Data
Sep. 22, 2000 (JP) 2000-289513

(51) Int. Cl. H01L 21/301; H01L 21/46; H01L 21/78

(52) U.S. Cl. 438/460; 438/462

(57) ABSTRACT

A method for manufacturing semiconductor devices comprising a step in which an adhesive layer used to bond dies cut out of a wafer to another member is formed on the front surface of the wafer that has desired integrated circuits, and a step in which a thin film conversion treatment is performed from the back surface side on the wafer in which recessed grooves used for separation of dies have been formed from the front surface side and on which the adhesive layer has been formed, until the recessed grooves are exposed.

### BACKGROUND OF THE INVENTION

1. Field of the Invention

The present invention relates to a method for manufacturing semiconductor devices and more particularly to a semiconductor device manufacturing method with which the size of semiconductor devices can be reduced and the efficiency of the manufacturing process can increase.

2. Prior Art

Semiconductor devices are manufactured by forming numerous desired integrated circuits on a wafer (semiconductor substrates), and then forming numerous dies (semiconductor elements) by dicing (splitting) the wafer into the individual integrated circuits. The integrated circuits are formed by diffusing impurities into the interior parts of wafers from the surfaces thereof and then forming insulating films and conductive films on the surfaces of the wafers.

While the thickness of the integrated circuit portions of a wafer is around a few microns, the thickness of the wafer is several hundred microns. The reason that the wafers are thus made much thicker than the integrated circuit portions is to endow the wafers with strength so as to prevent damage to the wafers during handling. However, such a large wafer thickness hinders a reduction in the overall size of the semiconductor devices.

Conventionally, therefore, the thickness of the dies is reduced by grinding the back surfaces of the wafers or dies (back grinding method). With this back grinding method, if dicing is performed after grinding, the dies that have been converted into thin films tend to be damaged. Accordingly, a method in which dicing is performed before grinding, i.e., the DBG (dicing before grinding) method, is expected to show promise as a technique for manufacturing thin dies at a good yield.

In the DBG method, first as shown in FIG. 4A recessed grooves 39 used for separation are formed in step (a) by means of cutting with, for instance, a diamond blade in the surface of a wafer 31 that constitutes the circuit formation surface on which desired circuits are formed (the circuit formation surface being the upper surface of the wafer. This is called the half-dicing process. Next, in step (b) the wafer 31 is turned upside down, and a back grinding tape (called a “BG tape”) 40 is bonded to the circuit formation surface, which is the lower surface side in FIG. 4A. Then, grinding is performed in step (c) by means of a back grinder (not shown) from the back surface side, which is now the upper surface, until the recessed grooves 39 are exposed, and polishing or chemical etching is further performed. As a result, the wafer 31 is separated into individual dies 43. The wafer 31 is again inverted and bonded to a wafer holding tape 45 in step (d). Next, the BG tape 40 is removed in step (e). Finally, in step (f) the dies 43 are picked up by a push-up pin 46 and transported so as to be mounted on a board or package (not shown).

In order to accelerate the bonding process between the dies and package (or between the dies and other dies in the case of a so-called die stacked system in which a plurality of dies are stacked), a method is known in which an adhesive tape which has an adhesive layer formed on both sides is bonded to dies. This is disclosed in, for example, Japanese Patent Application Laid-Open (Kokai) No. H11-204720.

In this method, as seen from FIG. 5, an adhesive tape 57 is first bonded in step (a) to the back surface of a heated wafer 51, which is not the circuit formation surface, and a wafer holding tape 65 is separately bonded to a wafer ring 64. The adhesive tape 57 may be bonded beforehand to the upper surface of the wafer holding tape 65 instead of being bonded to the wafer 51. Next, in step (b), the wafer 51 is bonded to the wafer ring 64 while being a positioning is made with respect to the wafer ring 64. Then, the wafer 51 and bonding tape 57 are completely cut by means of a dicing device in step (c), and the dies 63 are finally picked up by a push-up pin 66 in step (d). The dies 63 thus formed may be bonded to the surface of a board 67 by the adhesive force of the adhesive tape 57, or, in cases where a high density is required, the dies 63 may be stacked on top of other dies 63 and bonded.

In the above DBG method, when a an adhesive tape is used, the process is executed in the following manner: after individual dies 43 are integrally held on the BG tape 40 as a result of the steps (a) through (c) in FIG. 4B, the back-grounded back surfaces of the dies 43 are bonded to the upper surface of the wafer holding tape 45 (to which the adhesive tape 77 has been bonded beforehand) in step (d), then the BG tape is removed in step (e), and the dies 43 are picked up by the push-up pin 46 in step (f).

However, in this method, since dicing of the adhesive tape 77 (splitting of the adhesive tape 77 in accordance with the shapes of the dies) is not performed, individual dies 43 with an adhesive layer consisting of the adhesive tape 77 formed thereon are not obtainable. Accordingly, in addition to the half-dicing process of step (a), a step for dicing only the adhesive tape 77 is additionally required.

Furthermore, individual dies 43 that have an adhesive layer formed on each die might be obtained by way of bonding a piece of adhesive tape (not shown) corresponding to the size of the dies 43 to the back surface side (which is not the circuit formation surface this back surface side is the upper surface in the figures) of each die 43 in the state of step (e) of FIG. 4B in which the dies have been split following back grinding. Individual dies 43 that have an adhesive layer formed on each die might be obtained also by way of forming an adhesive layer (not shown) consisting of an adhesive material by screen printing on the back surface side of each die 43. In such cases, however, bonding or printing is performed on split dies 43; thus, the positioning precision with respect to the individual dies 43 deteriorates, and shifting and protrusion of the pieces of adhesive tape or adhesive layer beyond the edges of the dies 43 occur.

So as to obtain positioning precision during the formation of the adhesive layer, it is desirable that the adhesive layer be formed on the wafer 31 or 51 prior to splitting the wafer into individual dies 43 or 63, i.e., prior to back grinding. However, in all of the conventional methods described above, the adhesive layer is formed on the back surface side (which is not the circuit formation surface) of the wafer 31 or 51. In addition, grinding is likewise performed on the back surface side of the wafer 31 or 51. Accordingly, in such prior art the formation of the adhesive layer must necessarily be performed after back grinding, i.e., after the wafer 31 or 51 has been split into individual dies 43 or 63. Consequently, positioning precision of the adhesive layer and reduction in the size of the semiconductor device by means of the DBG method cannot be simultaneously accomplished.

### SUMMARY OF THE INVENTION

Accordingly, the object of the present invention is to provide a method that accomplishes both positioning precision of an adhesive layer and a size reduction of a semiconductor device that is formed by the DBG method.

The above object is accomplished by unique steps for a semiconductor device manufacturing method of the present invention that comprises:

an adhesive layer formation process in which an adhesive layer that is used to bond dies cut out from a wafer to another member is formed on the front surface of a wafer that has desired circuits thereon, and

a thin film conversion treatment process in which the wafer, which has thereon the adhesive layer and in which recessed grooves used for separation is to be formed from the front surface side, is ground from the back surface side thereof until the recessed grooves are exposed.

In this method, an adhesive layer, which is used to bond dies that are cut from a wafer to another member, is formed on the surface of the wafer on which desired circuits are formed (in the adhesive layer formation process); and then a thin film conversion treatment (that grinds the wafer to make it thinner) is performed from the back surface side of the wafer, in which recessed grooves used for separation are to be formed from the front surface side and on which the adhesive layer has been formed, until the recessed grooves are exposed (in the thin film conversion process). Thus, since the adhesive layer is formed on the wafer before the wafer is split into individual dies, i.e., prior to performing back grinding, good positioning precision of the formation of the adhesive layer can be obtained. In addition, since the adhesive layer is formed on the surface of the wafer on which desired circuits are formed, back grinding can be performed on the back surface side on which no circuits are formed. Thus, both positioning precision of the adhesive layer and reduction in size of the semiconductor device are accomplished by the back grinding.

The above method further includes a half-dicing process that forms, in the wafer, recessed grooves used for separation of dies; and this process is performed between the adhesive layer formation process and the thin film conversion process.

In this method, the half-dicing process that forms the recessed grooves used for separation is performed, and then the thin film conversion treatment is performed. Accordingly, the surface on which circuits are formed is covered by the adhesive layer at the time that half-dicing is performed, and there is no danger that dirt or foreign matter will adhere, during the half-dicing process, to the surface on which the circuits are formed; and thus defective products can be suppressed. Furthermore, even if the adhesive layers that correspond to the respective dies are formed so as to be connected to or continuous to each other, these connections are cut at the time of execution of half-dicing. Accordingly, it would not be a problem that the adhesive layers that correspond to the respective dies are formed continuous to each other. Thus, the positioning precision of the adhesive layers can be improved even further.

The above-described semiconductor device manufacturing method of the present invention may further include a holding step in which a holding member which holds a plurality of dies as an integral unit is bonded to the adhesive layer. The holding process is performed between the adhesive layer formation process and the thin film conversion process.

In this method that contains the holding step, the holding member which is used for holding a plurality of dies as an integral unit is bonded to the adhesive layer (in the holding process), then the thin film conversion treatment is performed. Accordingly, the individual dies can be held as an integral unit throughout the thin film conversion treatment, and the handling characteristics are enhanced.

Furthermore, in the present invention the adhesive layer covers all the area of the front surface of the wafer except for the metal bumps. Since the adhesive layer covers all the front surface except for the metal bumps, subsequent bonding to the metal bumps can be performed without any hindrance.

In addition, when the above-described “another member” is a die, the density of the semiconductor device can increase by way of stacking the dies.

### BRIEF DESCRIPTION OF THE DRAWINGS

FIG. 1 shows the adhesive layer formation process in cross section comprising the steps (a), (b), (c) and (d) according to one embodiment of the present invention;

FIG. 2 is a top view of the wafer with the adhesive layer and recessed grooves formed thereon;

FIG. 3 show the process of the present invention shown in cross section in which (a) shows the half-dicing step, (b) shows the holding step effected by the bonding of a BG tape, (c) shows the thin film conversion step effected by back grinding, etc., (d) shows the step of bonding to the wafer holding tape, (e) shows the BG tape removing step, and (f) shows the die pick-up step;

FIG. 4A shows steps (a) through (f) of a conventional semiconductor device manufacturing method that uses the DBG method; and

FIG. 4B shows steps (a) through (f) of a conventional semiconductor device manufacturing method that uses adhesive tape in the DBG method; and

FIG. 5 shows step (a) through (d) of a conventional semiconductor device manufacturing method that uses an adhesive tape.

### DETAILED DESCRIPTION OF THE INVENTION

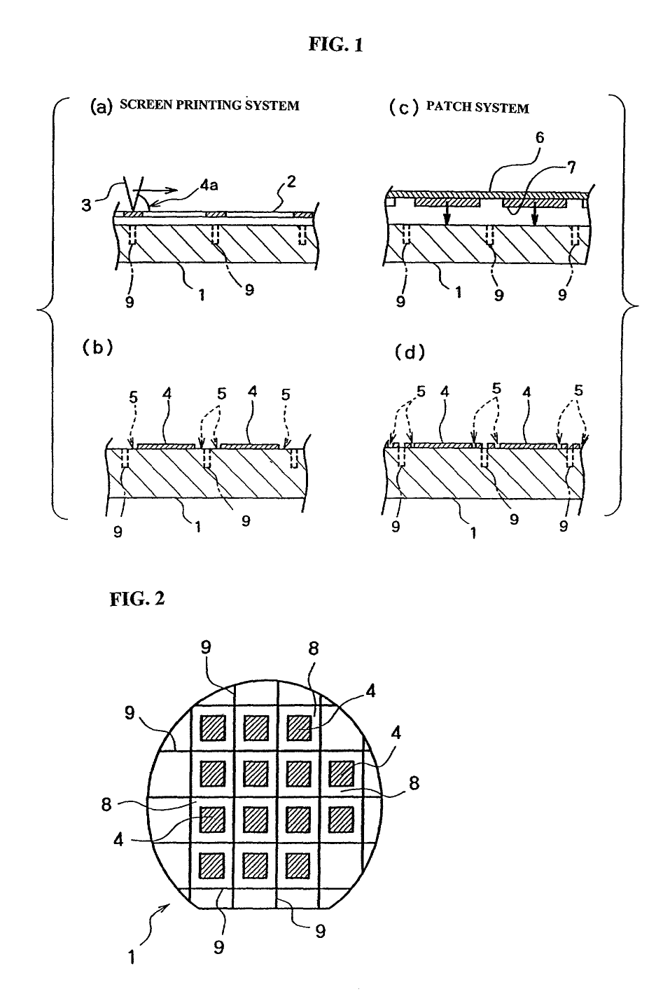

An embodiment of the present invention will be described with reference to FIGS. I through 3. The wafer in step (a) FIG. 1 has integrated circuits (not shown) formed on the surface thereof that is on the upper side in FIG. 1.

First, an adhesive agent 4a is applied to this surface using a screen 2 and squeegee 3. As a result, an adhesive layer 4 is formed in step (b).

The adhesive layer 4 covers portions of the surface of the wafer 1 on which the integrated circuits are formed, and it covers all portions of this surface except for the metal bumps that are formed at positions that are referred to by reference numerals 5.

The adhesive layer 4 may also be formed on both the insides and outsides of dies with respect to the metal bumps 5 as shown in step (d), or the adhesive layer 4 may be formed so as to surround the entire circumference of each metal bump 5. Though not shown, the adhesive layers 4 corresponding to the respective dies 13 may be formed so as to be connected to or continuous to each other.

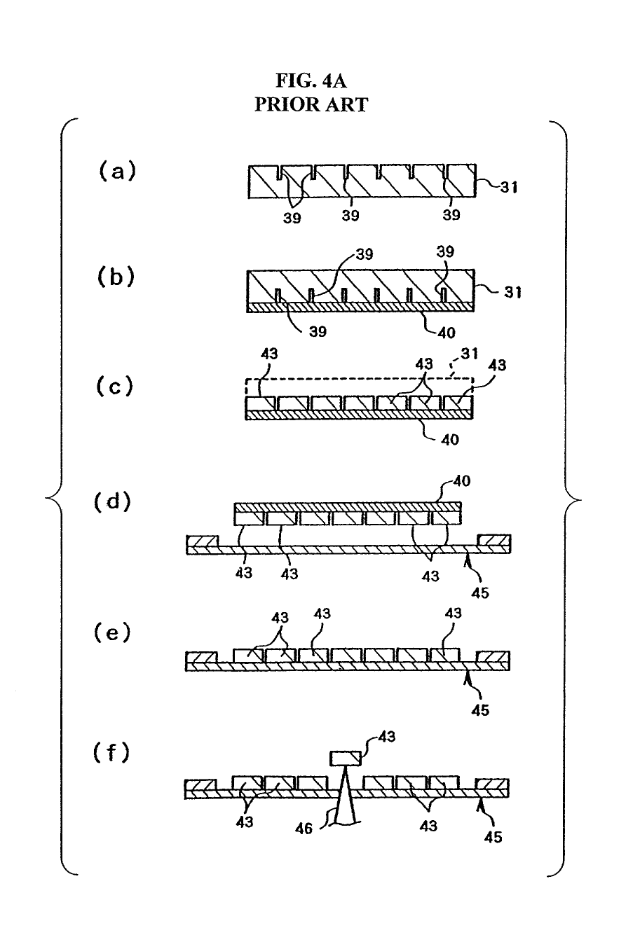

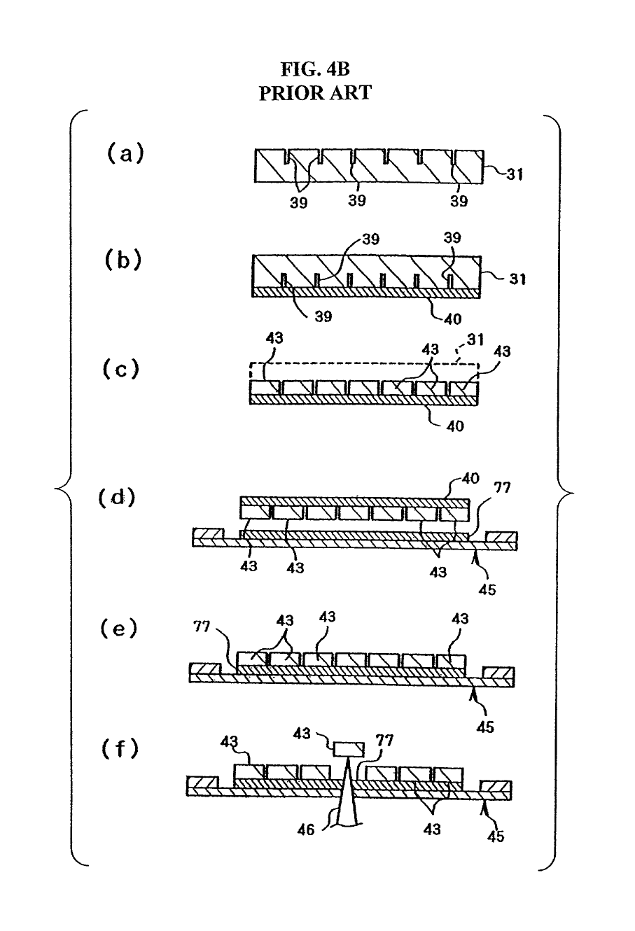

Next, in step (a) in FIG. 3, cutting is performed by means of, for instance, a diamond blade from the front surface of the wafer 1, so that recessed grooves 9 used for separation are formed (half-dicing process). The recessed grooves 9 have an intermediate depth in terms of the thickness of the wafer 1. As a result, a state is created in which the adhesive layers 4 are formed on the front surface of the wafer 1 for each of the numerous integrated circuits that are formed and in which the recessed groove 9 used for separation are formed as shown in step (a) of FIG. 3.

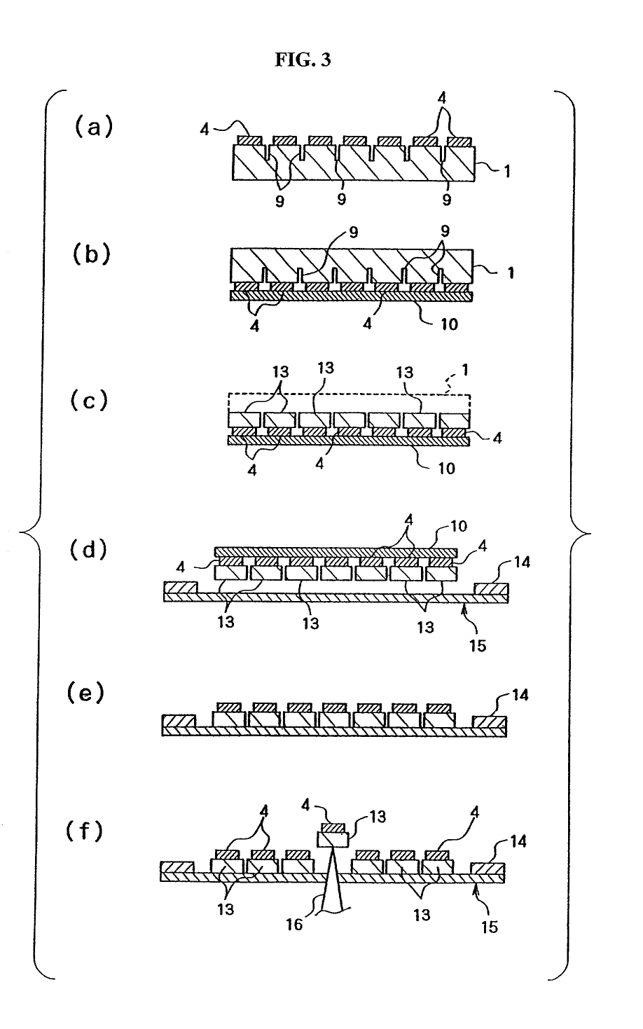

Next, in step (b), the wafer 1 is turned upside down, a BG tape 10 is caused to contact the circuit formation surface, which is now on the lower side in FIG. 2, and the BG tape 10 is bonded to the wafer by the adhesive force of the adhesive layers 4.

In the next step (c), grinding, i.e., back grinding, is performed by means of a back grinder (not shown) from the back surface side of the wafer 1, which is now the upper surface in FIG. 3, until the recessed grooves 9 are exposed; and polishing or chemical etching is further performed. As a result, the wafer 1 is separated into individual dies 13.

Then, in step (d), the wafer 1 is again inverted and is bonded to a wafer holding tape 15 that is bonded to a wafer ring 14. Then, in step (e) the BG tape 10 is removed.

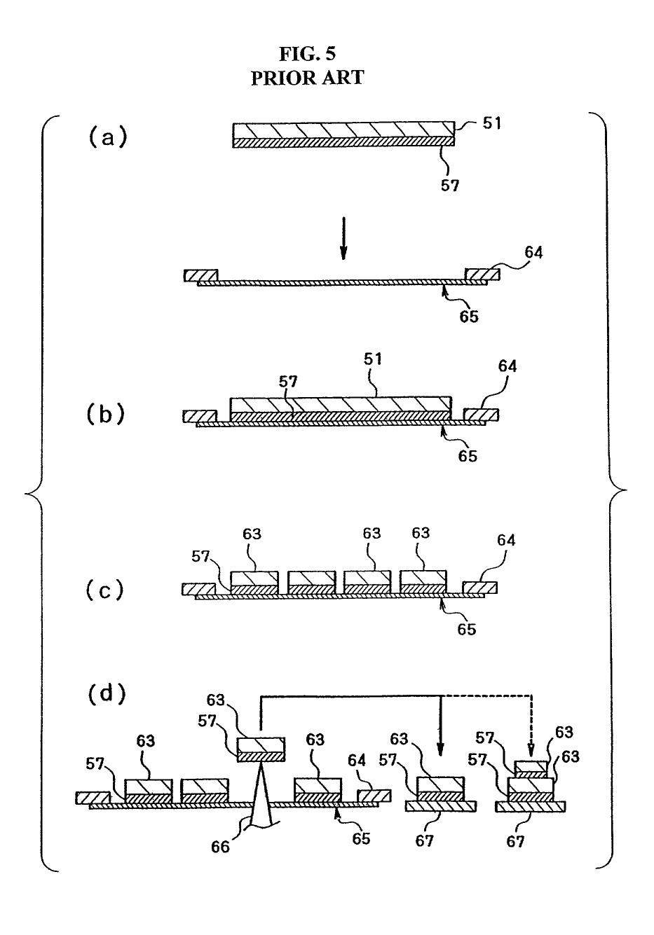

Finally, in step (f), dies 13 are picked up by a push-up pin 16 and are transported for mounting on a board or package (not shown). As shown in step (d) of FIG. 5, the transported dies 13 may be singly bonded to another member such as a board or package, etc. or may be stacked on top of other dies 13 and bonded.

In the above embodiment, the adhesive layer 4 which is used to bond the dies 13 cut out from a wafer 1 to other members is formed on the front surface of the wafer 1 on which desired integrated circuits are formed (adhesive layer formation process). Then, a thin film conversion treatment is performed from the back surface side of the wafer 1 in which recessed grooves 9 used for separation are to be formed from the front surface side and on which the adhesive layer 4 has been formed, and this thin film conversion treatment is performed until the recessed grooves 9 are exposed (thin film conversion treatment). Thus, in the above embodiment, the adhesive layer 4 is formed on the wafer 1 before the wafer 1 is split into dies 13, i.e., before back grinding is performed. Accordingly, high positional precision of the formation of the adhesive layer 4 is obtained. Since the adhesive layer 4 is formed on the front surface of the wafer on which the desired integrated circuits have been formed, back grinding can be performed from the back surface which is not a circuit-formed surface. Accordingly, both positioning precision of the adhesive layer 4 and a reduction in the size of the semiconductor device by means of the back grinding method can be achieved in the present invention.

Furthermore, in the above embodiment, the half-dicing that forms the recessed grooves 9 used for separation is performed after the formation of the adhesive layer 4, and a thin film conversion treatment is performed after this. The half-dicing can be performed prior to the formation of the adhesive layer 4; and this manner of process falls within the scope of the present invention. However, particularly in the above embodiment, half-dicing is performed following the formation of the adhesive layer 4; accordingly, the circuit formation surface is covered by the adhesive layer 4 at the time that half-dicing is performed. There is thus no danger that dirt or foreign matter will adhere to the circuit formed surface when half-dicing is performed, and the generation of defective products can be avoided. In addition, even if the adhesive layers 4 that correspond to the respective dies 13 are formed continuous to each other, such a continuation is cut when half-dicing is performed. Accordingly, it is possible to form the adhesive layers 4, which correspond to the respective dies 13, so as to be continuous to or connected to each other. Thus, the positioning precision of the adhesive layers 4 is significantly high in the present invention.

Furthermore, in the above embodiment, a BG tape 10 that is used as a holding member that holds a plurality of dies 13 as an integral unit is bonded to the adhesive layer 4 after the adhesive layer 4 is formed (holding process), and then the thin film conversion treatment is performed on the wafer 1 after this. Accordingly, the individual dies 13 are held as an integral unit throughout the thin film conversion treatment, and an excellent handling characteristics are obtained in the present invention.

In addition, in the shown embodiment, the adhesive layer 4 covers all areas of the front surface of the wafer 1 except for the metal bumps 5. Accordingly, subsequent bonding to the metal bumps can be performed without hindrance.

Furthermore, the adhesive layer 4 is formed by applying an adhesive agent 4a to the wafer 1 as a coating. However, it is also possible, instead, to employ steps in which the adhesive tape 7 is transferred so that the portions of the front surface of the wafer 1 on which the integrated circuits are formed are covered and then all portions except for the metal bumps 5 are covered. In instead of adhesive tapes, however, a tape or sheet made of a thermoplastic resin can be used, and this provides substantially the same effect as that of the embodiment described above.

1. A semiconductor device manufacturing method comprising the steps of:
forming an adhesive layer on a first surface of a wafer on which desired circuits are provided, said adhesive layer being to bond a die cut out from a wafer to another member, and
performing a thin film conversion treatment on said wafer which has thereon said adhesive layer and in which recessed grooves used for separation is to be formed from said first surface side, said thin film formation treatment being performed from a second surface side of said wafer until said recessed grooves are exposed.

2. The semiconductor device manufacturing method according to claim 1, further comprising the step of performing a half-dicing that forms said recessed grooves used for separation, said step of performing a half-dicing being conducted between said step of forming said adhesive layer and said step of performing said thin film conversion treatment.

3. The semiconductor manufacturing method according to claim 1 or 2, further comprising the step of performing a holding process that bonds a holder to said adhesive layer so that said holder holds a plurality of said dies as an integral unit, said step of performing a holding process being conducted between said step of forming said adhesive layer and said step of performing said thin film conversion treatment.

4. The semiconductor device manufacturing method according to claim 1 or 2, wherein said adhesive layer covers portions of said first surface excluding metal bumps.

5. The semiconductor device manufacturing method according to claim 3, wherein said adhesive layer covers portions of said first surface excluding metal bumps.

6. The semiconductor device manufacturing method according to claim 1 or 2, wherein said another member is a die.

7. The semiconductor device manufacturing method according to claim 3, wherein said another member is a die.

8. The semiconductor device manufacturing method according to claim 4, wherein said another member is a die.

9. The semiconductor device manufacturing method according to claim 5, wherein said another member is a die.
